(19) United States
(12) Patent Application Publication
(10) Pub. No.: US 2014/0246658 A1
(43) Pub. Date: Sep. 4, 2014

(54) ORGANIC ELECTROLUMINESCENT DEVICE AND METHOD FOR MANUFACTURING THE ORGANIC ELECTROLUMINESCENT DEVICE

(71) Applicant: Pioneer Corporation, Kawasaki-shi, Kanagawa (JP)

(72) Inventors: Ayako Yoshida, Kawasaki-shi (JP); Satoshi Miyaguchi, Kawasaki-shi (JP); Shinich Ishizuka, Kawasaki-shi (JP)

(73) Assignee: Pioneer Corporation, Kawasaki-shi (JP)

(21) Appl. No.: 14/235,397

(22) PCT Filed: Jul. 28, 2011
(86) PCT No.: PCT/JP2011/067304

§ 371 Date: Apr. 18, 2014

(51) Int. Cl. H01L 27/32; H01L 51/56; H01L 51/52

(52) U.S. Cl. CPC H01L 27/3225; H01L 51/5246; H01L 51/56
USPC 257/40; 438/23

(57) ABSTRACT

On or above a substrate, a first electrode layer and a connection wiring connected to the first electrode layer are provided. On or above the first electrode layer, an organic function layer made of an organic material and a second electrode layer are deposited so as to construct an organic EL element. A sealing layer is provided to cover the organic EL element and the connection wiring. The connection wiring includes a fuse part to cause a break resulting from an overcurrent. The fuse part has an upper surface in contact with a gap layer.

### TECHNICAL FIELD

The present invention relates to an organic electroluminescent device and a manufacturing method therefore.

### BACKGROUND ART

The organic electroluminescent device (hereinafter referred to as the organic EL device) is a self-luminous surface emitting device which provides a high visibility and a broad emission spectrum, and can be driven at a low voltage. For these reasons, studies have been actively made to put the organic EL device into practical use such as for display and lighting applications. For example, the organic EL device includes a first electrode (anode), a hole transport layer, a light-emitting layer, an electron transport layer, and a second electrode (cathode), which are sequentially deposited in that order on a glass substrate. The organic EL device provides electroluminescence by current injection and requires a larger current to flow therethrough when compared with a field device such as a liquid crystal display device.

Since the organic EL device is configured such that an organic functional layer provided between the anode and the cathode has a thickness of the order of submicron, there is a possibility that minute dust particles or defects in the organic functional layer may cause a current leak. For example, in a display device, a current leak in one cell that constitutes a pixel may possibly lead to damage to surrounding cells.

As a technique for preventing a ripple effect of such damage on surrounding cells, disclosed in Patent Literature 1 is a technique for interrupting a short-circuit current by providing each of a plurality of pixels with an electrode which has a break function to cause a break resulting from an overcurrent in the event of a short circuit.

Disclosed in Patent Literature 2 is a technique for self-repairing a short circuit by applying a reverse bias voltage between the electrodes so as to evaporate the electrode material.

Disclosed in Patent Literature 3 is a technique for repairing a short circuit by irradiating the short circuit with a laser beam so as to melt and remove the same.

### CITATION LIST

### Patent Literature

Patent Literature 1: Japanese Patent Application Laid-Open No. 2001-196190

Patent Literature 2: Japanese Patent Application Laid-Open No. 2004-214084

Patent Literature 3: Japanese Patent Application Laid-Open No. 2003-229262

### SUMMARY OF INVENTION

### Technical Problem

The organic EL device has a sealed structure because the device could rapidly deteriorate due to oxygen or water. The sealed structure typically has a hollow sealed structure such as that of a sealed can. However, in view of recent increasing demands for reduction in thickness or improvement in flexibility of the device, the hollow sealed structure is difficult to meet those demands. The sealed structure that can reduce the thickness of the device may be a sealed structure for sealing by using a plate-shaped material such as a glass plate, or a sealed structure for covering and then sealing the entire organic EL element with a thin film of an inorganic material such as SiO₂ or SiNx. Such a structure is referred to as a solid sealed structure in which the device is sealed with a plate-shaped material or a thin film which is in close contact with the components thereof.

When a device having the solid sealed structure is provided with an electrode that may be broken due to an overcurrent as disclosed in Patent Literature 1 above, it is conceivable that the following problem may occur. That is, when the electrode is broken due to an overcurrent, the material of the electrode is melted while being deformed and expanded. The device having the solid sealed structure is configured so as not to have a space in which the melted electrode material is scattered because respective layers constituting the device are formed in intimate contact with each other. Thus, there is a possibility that the electrode may not be properly broken even when an overcurrent flows therethrough or that the electrode may be broken once but the break may be repaired due to a pressure from a sealing layer, causing the recurrence of a leak. There is also a possibility that the sealing layer may be ruptured due to impact or heat caused when the electrode is broken, thereby impairing the sealing performance.

The present invention has been developed in view of the aforementioned problems. It is an object of the present invention to provide an organic electroluminescent device with a wiring having a break function to cause a break when an overcurrent flows therethrough, the organic electroluminescent device being capable of allowing the aforementioned break to lead to a proper break due to an overcurrent while preventing the sealing layer from being damaged due to heat or impact that follows the break of the wiring and the recurrence of a leak due to a pressure from the sealing layer. It is another object of the present invention to provide a method for manufacturing the organic electroluminescent device.

### Solution to Problem

An organic electroluminescent device of the present invention includes a substrate; a first electrode layer provided on or above the substrate; an organic functional layer which includes an organic material and is provided on or above the first electrode layer; a second electrode layer provided on or above the organic functional layer; a connection wiring provided on or above the substrate and connected to the first electrode layer or the second electrode layer; and a sealing layer covering a layered structure including the first electrode layer, the second electrode layer, the organic functional layer, and the connection wiring, the organic electroluminescent device being characterized in that the connection wiring includes a fuse part to be broken due to an overcurrent, and the fuse part is in contact with a gap layer.

On the other hand, a method for manufacturing an organic electroluminescent device of the present invention is characterized by including the steps of: forming a first electrode layer on or above a substrate; forming, on or above the first electrode layer, an organic functional layer containing an organic material; forming a second electrode layer on or above the organic functional layer; forming, on or above the substrate, a connection wiring connected to the first electrode layer or the second electrode layer and having a fuse part to be broken due to an overcurrent; forming a sealing layer covering a layered structure including the first electrode layer, the second electrode layer, the organic functional layer, and the connection wiring; and removing a portion covering an upper surface of the fuse part of the sealing layer.

Furthermore, a method for manufacturing an organic electroluminescent device of the present invention is characterized by including the steps of: forming a first electrode layer on or above a substrate; forming, on or above the first electrode layer, an organic functional layer containing an organic material; forming a second electrode layer on or above the organic functional layer; forming, on or above the substrate, a connection wiring connected to the first electrode layer or the second electrode layer and having a fuse part to be broken due to an overcurrent; forming a bank surrounding the fuse part; forming an adhesive layer covering a layered structure while forming a gap layer with the bank employed as a sidewall above the fuse part, the layered structure including the first electrode layer, the second electrode layer, the organic functional layer, and the connection wiring; and forming a seal plate on or above the adhesive layer.

### BRIEF DESCRIPTION OF DRAWINGS

FIG. 1 is a plan view illustrating the structure of an organic EL device according to a first embodiment of the present invention.

FIG. 2(a) is a partial plan view illustrating the structure of the organic EL device according to the first embodiment of the present invention; FIG. 2(b) is a cross-sectional view taken along line 2b-2b of FIG. 2(a); and FIG. 2(c) is an enlarged plan view illustrating a fuse part according to an embodiment of the present invention.

FIGS. 3(a) to (e) are a plan view illustrating a method for manufacturing the organic EL device according to the first embodiment of the present invention.

FIGS. 4(a) to (e) are a cross-sectional view taken along line 4a-4a, line 4b-4b, line 4c-4c, line 4d-4d, and line 4e-4e of FIGS. 3(a) to (e), respectively.

FIG. 5 is a cross-sectional view illustrating the structure of an organic EL device according to a second embodiment of the present invention.

FIG. 6 is a cross-sectional view illustrating the structure of an organic EL device according to a third embodiment of the present invention.

FIG. 7 is a plan view illustrating the structure of an organic EL device according to another embodiment of the present invention.

### DESCRIPTION OF EMBODIMENTS

An organic electroluminescent device according to the present invention includes: a substrate; a first electrode layer provided on or above the substrate; an organic functional layer including an organic material and provided on or above the first electrode layer; a second electrode layer provided on or above the organic functional layer; a connection wiring provided on or above the substrate and connected to the first electrode layer or the second electrode layer; and a sealing layer covering a layered structure including the first and second electrode layers, the organic functional layer, and the connection wiring. The connection wiring includes a fuse part to be broken due to an overcurrent with the upper surface of the fuse part in contact with a gap layer. Such a structure provides a space above the fuse part. This allows even a device having a solid sealed structure to be capable of scattering and deforming a metal forming the fuse when an overcurrent flows through the connection wiring, thus providing a proper break. Furthermore, since the gap layer will interrupt heat or impact in the case of a break in the connection wiring, it is possible to prevent damage to the sealing layer and thus maintain the seal performance. Furthermore, since the gap layer is interposed between the connection wiring including the fuse part and the sealing layer, it is possible to prevent the recurrence of a leak caused by a break of the fuse part being repaired by a pressure from the sealing layer.

Now, referring to the drawings, the present invention will be described below in accordance with the embodiments. Note that in the drawings to be referred to below, substantially like or equivalent components or parts will be denoted with the same reference symbols.

### First Embodiment

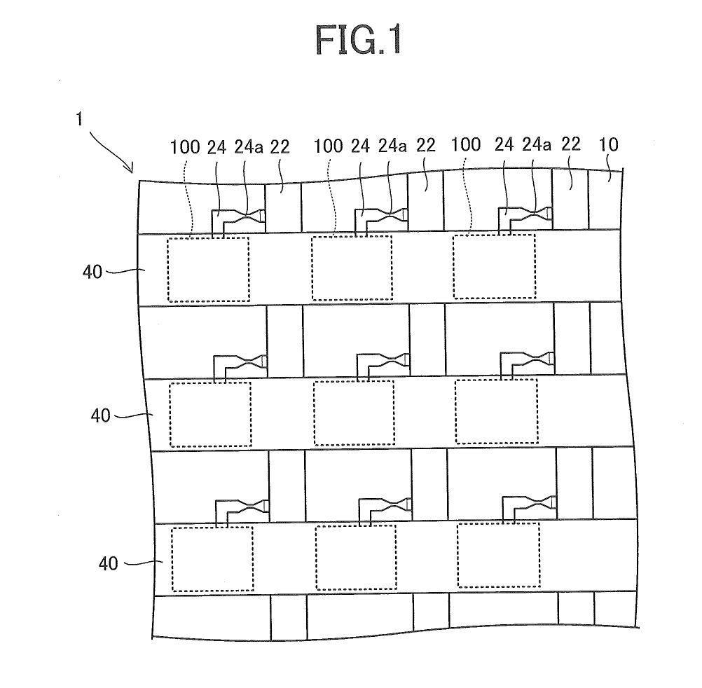

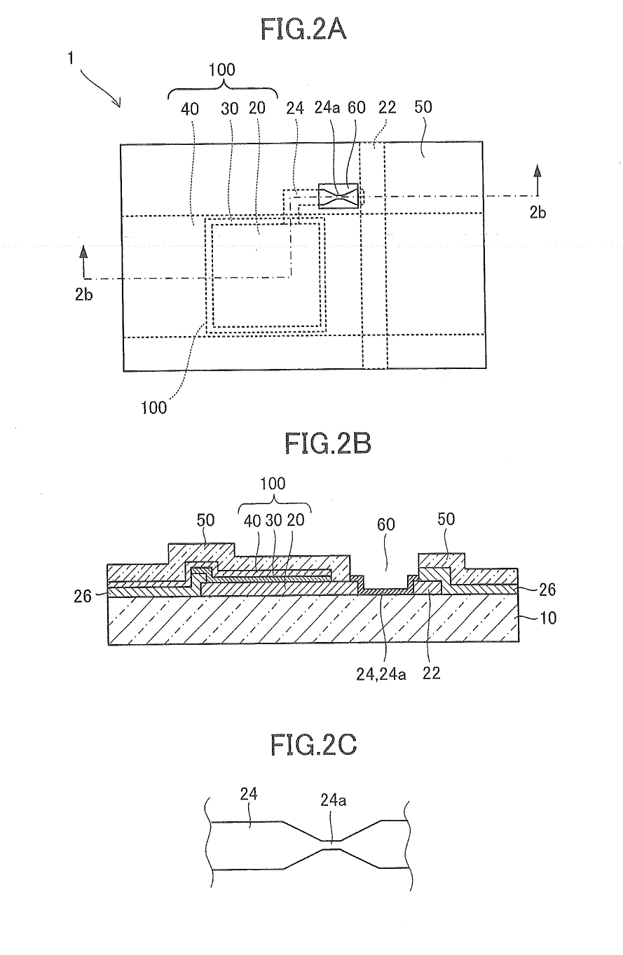

FIG. 1 is a plan view illustrating the structure of an organic EL device 1 according to an embodiment of the present invention. FIG. 2(a) is a partial enlarged plan view illustrating the structure of the organic EL device 1 according to the embodiment of the present invention; FIG. 2(b) is a cross-sectional view taken along line 2b-2b of FIG. 2(a); and FIG. 2(c) is an enlarged plan view illustrating a fuse part according to the embodiment of the present invention. Note that to facilitate understanding, FIG. 1 illustrates the structure with an insulating film 26 and a sealing layer 50 eliminated.

The organic EL device 1 is a display device which employs a so-called dot matrix display mode in which each of a plurality of organic EL elements 100 acts as a pixel. That is, a plurality of power-supply wirings 22 are disposed so as to intersect a plurality of second electrodes 40 on a substrate 10, and the organic EL elements 100 are each disposed in the vicinity of these intersections. Each organic EL element 100 has a layered structure in which a first electrode 20, an organic functional layer 30, and the second electrode 40 are deposited one on another. The second electrode 40 extends in a direction orthogonal to the power-supply wiring 22 and is shared by a plurality of organic EL elements. Each organic EL element 100 is supplied with drive power through the power-supply wiring 22 and a connection wiring 24. The organic EL device 1 is a so-called bottom emission type display device which emits light produced in the organic functional layer 30 through the substrate 10.

The substrate 10 is made of an optically transparent material such as glass. The first electrode 20 or an anode provided on the substrate 10 is formed by patterning, in a rectangular shape, an optically transparent conductive metal oxide such as Indium Tin Oxide (ITO) or Indium Zinc Oxide (IZO) which is approximately 100 nm in thickness. Furthermore, the power-supply wiring 22 for supplying drive power to the organic EL element 100 is provided on the substrate 10 so as to be spaced apart from the first electrode 20.

The connection wiring 24 electrically connects between the power-supply wiring 22 and the first electrode 20 on the substrate 10. The connection wiring 24 has a break function to cause a break when an excessive current is injected from the power-supply wiring 22 to the organic EL element 100, thereby interrupting the inflow of a short-circuit current to the organic EL element 100. The connection wiring 24 is made, for example, of an alloy composed mainly of tin, bismuth, or lead so as to be broken at a desired current. More specifically, the connection wiring 24 is made of a tin-based alloy such as solder or a low melting point metal such as Wood's metal, Rose's metal, and Newton's alloy. Furthermore, the connection wiring 24 includes a fuse part 24a which is narrower in trace width than other portions and thus has a lower durability to current as compared with the other portions. That is, the fuse part 24a is configured to have a break when the organic EL element 100 is short-circuited causing an overcurrent to flow through the connection wiring 24. Note that it is also possible to form the fuse part by reducing the connection wiring 24 in thickness relative to the other portions or using a material having a further lowered melting point. Since each organic EL element 100 is connected with the connection wiring 24 having the fuse part 24a, even a short circuit occurring in a particular organic EL element would not cause a ripple effect of damage on another organic EL element.

The organic functional layer 30 is formed by depositing, on the first electrode 20, a hole injection layer, a hole transport layer, a light-emitting layer, and an electron injection layer in that order. The hole injection layer is formed, for example, of copper phthalocyanine (CuPc) of approximately 10 nm in thickness; the hole transport layer is formed, for example, of α-NPD (Bis[N-(1-naphthyl)-N-phenyl]benzidine) of approximately 50 nm in thickness; the light-emitting layer is formed, for example, of Alq₃ (tris-(8-hydroxyquinoline)aluminum) of approximately 60 nm in thickness; and the electron injection layer is formed, for example, of lithium fluoride (LiF) of approximately 1 nm in thickness.

The second electrode 40 or the cathode is made, for example, of Al and provided to cover the organic functional layer 30. The second electrode 40 extends in a direction orthogonal to the direction in which the power-supply wiring 22 extends. The insulating layer 26 is inserted in between the second electrode 40, and the power-supply wiring 22 and the connection wiring 24 so as to electrically insulate the same from each other. The second electrode 40 may be made of an alloy having a relatively low work function such as Mg—Ag or Al—Li which is another preferred material therefore.

The sealing layer 50 is formed of a thin film made of an inorganic material such as SiNx, SiON, SiOx, AlOx, or AlN. The sealing layer 50 serves to entirely cover each of the aforementioned components of the organic EL device 1 so as to prevent entry of oxygen and moisture from outside. The sealing layer 50 is formed so as to be in close contact with the organic EL element. On the other hand, the upper surface of the fuse part 24a is in contact with a gap layer 60. That is, the sealing layer 50 is provided so as to avoid the fuse part 24a and thus has an opening at the position at which the fuse part 24a is formed. The upper surface of the fuse part 24a is exposed in the opening.

Note that in the aforementioned example, the connection wiring 24 is connected to the first electrode 20 or the anode. However, the connection wiring 24 may also be connected to the second electrode 40 or the cathode. In this case, it is necessary to form an insulating film between the connection wiring 24 and the first electrode 20.

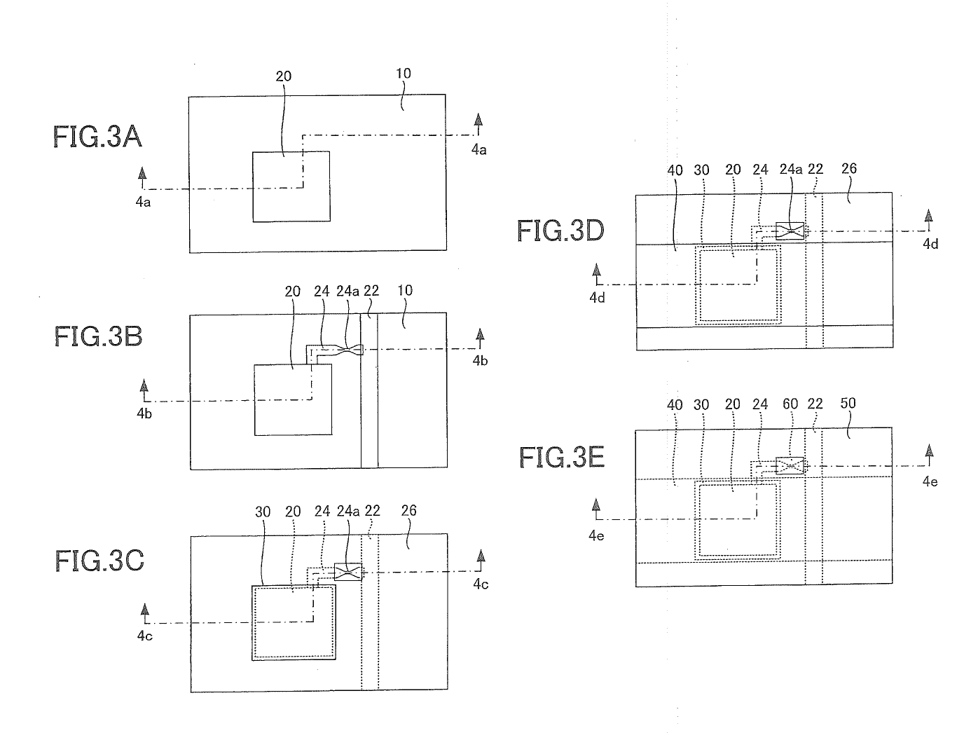

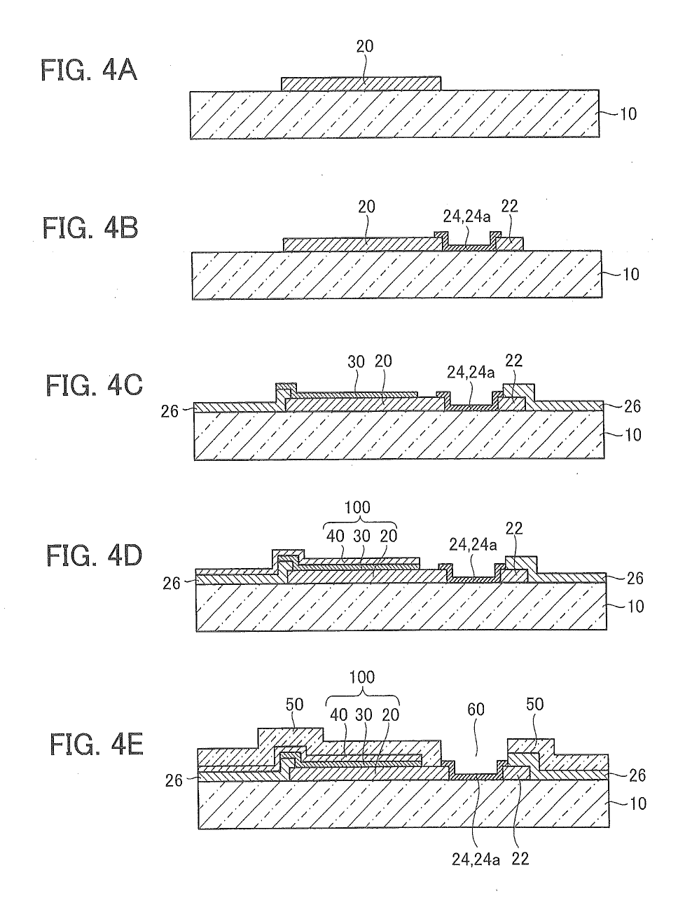

FIGS. 3(a) to (e) are a plan view illustrating a method for manufacturing the organic EL device 1 having the aforementioned structure. FIGS. 4(a) to (e) are a cross-sectional view taken along line 4a-4a, line 4b-4b, line 4c-4c, line 4d-4d, and line 4e-4e of FIGS. 3(a) to (e), respectively.

An optically transparent conductive metal oxide such as ITO or IZO is deposited to about 100 nm, for example, by sputtering on the optically transparent substrate 10 made of glass or the like, and then etched in a rectangular pattern to form the first electrode 20 (FIG. 3(a) and FIG. 4(a)).

Then, by the same technique as that for the first electrode 20, the power-supply wiring 22 of a low-resistance metal such as Al, Cu, Ag, or Au is formed at a position spaced apart from the first electrode 20 on the substrate 10. Subsequently formed, for example, by mask vapor deposition is the connection wiring 24 which is an alloy composed mainly of tin, bismuth, or lead, or more specifically, a tin-based alloy such as solder or a low melting point metal such as Wood's metal, Rose's metal, or Newton alloy. The connection wiring 24 is patterned to form the fuse part 24a thereon. That is, the connection wiring 24 is patterned so as to be locally reduced in width at the fuse part 24a (FIG. 3(b) and FIG. 4(b)).

Then, to cover the surfaces of the first electrode 20, the power-supply wiring 22, and the connection wiring 24, the material of the insulating film 26 or photoresist (or polyimide) is coated. Subsequently, the photoresist is patterned after an exposure and development step. Through these steps, the insulating film 26 is formed which has an opening in which the surface of the first electrode 20 and the surface of the fuse part 24a are exposed (FIG. 3(c) and FIG. 4(c)). Note that the material of the insulating film 26 and the method for patterning the insulating film 26 are not limited thereto. For example, the insulating film 26 may also be made of an inorganic material such as SiO₂ and can be patterned by the well-known lift-off method or by etching using a resist mask formed by a well-known photolithographic technique.

Then, for example, by an ink jet method or by mask vapor deposition, the hole injection layer, the hole transport layer, the light-emitting layer, and the electron injection layer are sequentially deposited on the exposed first electrode 20 to form the organic functional layer 30. The hole injection layer is formed, for example, of copper phthalocyanine (CuPc) of approximately 10 nm in thickness; the hole transport layer is formed, for example, of α-NPD (Bis[N-(1-naphthyl)-N-phenyl]benzidine) of approximately 50 nm in thickness; the light-emitting layer is formed, for example, of Alq₃ (tris-(8-hydroxyquinoline)aluminum) of approximately 50 nm in thickness; and the electron injection layer is formed, for example, of lithium fluoride (LiF) of approximately 1 nm in thickness (FIG. 3(c) and FIG. 4(c)).

Then, using a mask having an opening corresponding to the pattern of the second electrode 40, Al or an electrode material is deposited by vapor deposition or the like in a desired pattern on the structure that has been obtained through each of the aforementioned steps. As a result, the second electrode 40 is formed that is connected to the organic functional layer 30 and extends in a direction orthogonal to the direction in which the power-supply wiring 22 extends. That is, the organic functional layer 30 is sandwiched between the first electrode 20 and the second electrode 40, while the second electrode 40 is isolated from the power-supply wiring 22 and the connection wiring 24 by the insulating layer 26 (FIG. 3(d) and FIG. 4(d)).

Then, while the upper surface of the fuse part 24a exposed in the opening of the insulating film 26 is covered with adhesive tape or the like, an inorganic material such as SiNx, SiON, SiOx, AlOx, or AlN is deposited e.g., by a plasma CVD method that enables isotropic deposition so as to entirely cover the structure obtained through each of the aforementioned steps, thereby forming the sealing layer 50. The sealing layer 50 is formed in close contact with the organic EL element 100 and is also formed on the adhesive tape that is covering the fuse part 24a. Subsequently, the adhesive tape is stripped off to remove the portion that is covering the fuse part 24a of the sealing layer 50. Thus, the opening of the sealing layer 50 is formed above the fuse part 24a, and as a result, the gap layer 60 is formed above the fuse part 24a. That is, the upper surface of the fuse part 24a is exposed in the opening of the sealing layer 50 (FIG. 2(e) and FIG. 3(e)). Through each of the steps above, the organic EL device 1 is completed.

The organic EL device 1 according to this embodiment is configured such that a space is formed by the gap layer 60 above the fuse part 24a. For this reason, when a short circuit between the first and second electrodes may cause an overcurrent to flow into the organic EL element 100 through the connection wiring 24 from the power-supply wiring 22, the metal forming the connection wiring 24 can be melted and evaporated while being deformed and expanded, thereby providing a proper break. This interrupts a current being supplied to the organic EL element 100. Furthermore, since the gap layer 60 is provided above the upper surface of the fuse part 24a, the connection wiring 24 being deformed and expanded at the fuse part 24a would not have an effect on the sealing layer 50. As described above, since the organic EL device according to this embodiment is configured such that the heat or impact caused by a break of the connection wiring 24 is interrupted by the gap layer 60, the sealing layer 50 is not ruptured and thus the seal performance is maintained. Furthermore, since the fuse part 24a and the sealing layer 50 are formed in a noncontact fashion, the break would not be repaired by the pressure from the sealing layer 50, thereby causing a leak to occur again.

### Second Embodiment

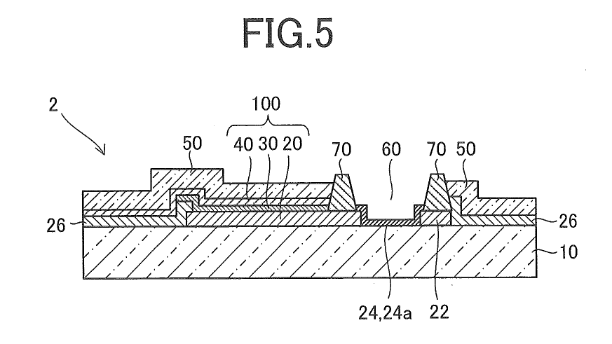

FIG. 5 is a cross-sectional view illustrating the structure of an organic EL device 2 according to a second embodiment of the present invention. The organic EL device 2 is different from the organic EL device 1 according to the first embodiment described above in that there is provided a bank (partition wall) 70 for surrounding the gap layer 60. That is, the bank 70 covers the side of the opening of the sealing layer 50 that defines the gap layer 60. Partially removing the sealing layer 50 and thereby providing the opening in order to form the gap layer 60 would lead to a possibility that oxygen or water may enter through the opening to thereby cause the organic EL device to deteriorate. Since the organic EL device 2 according to this embodiment is configured such that the bank 70 is provided so as to cover the side of the opening of the sealing layer 50 that defines the gap layer 60, it is possible to prevent entry of oxygen or water through the opening. The components other than the bank 70 are the same as those of the organic EL device 1 according to the first embodiment described above.

The organic EL device 2 is manufactured, for example, in the following processes. On the substrate 10 are formed the first electrode 20, the power-supply wiring 22, and the connection wiring 24 having the fuse part 24a. Next, the bank 70 is formed so as to surround the connection wiring 24 (the fuse part 24a). The bank 70 is formed, for example, by depositing an organic material such as photosensitive polyimide and thereafter patterning the same by the exposure and development process. The bank 70 forms the partition wall for surrounding the connection wiring 24 that includes the fuse part 24a. For example, the bank 70 can be formed on the first electrode 20 and the power-supply wiring 22. Next, the insulating film 26 is formed which has an opening for allowing the first electrode 20 and the upper surface of the fuse part 24a to be exposed. Next, the organic functional layer 30 is formed on the first electrode 20. Next, the second electrode 40 is formed which is connected to the organic functional layer 30 and extends in a direction orthogonal to the direction in which the power-supply wiring 22 extends.

Then, while the upper surface of the fuse part 24a is covered with adhesive tape or the like, the sealing layer 50 made of a thin film of an inorganic material is formed by a plasma CVD method so as to entirely cover the structure obtained through each of the aforementioned steps. The sealing layer 50 is formed in close contact with the organic EL element and also formed even on the adhesive tape that is covering the fuse part 24a. Subsequently, the adhesive tape is stripped off to remove the portion that is covering the fuse part 24a of the sealing layer 50, thereby forming the gap layer 60 above the fuse part 24a. Through each of the steps above, the organic EL device 2 is completed.

As in the case of the aforementioned first embodiment, the organic EL device 2 according to this embodiment is configured such that since the presence of the gap layer 60 allows a space to be formed above the fuse part 24a, the connection wiring 24 can properly have a break. Furthermore, since the heat or impact caused by a break of the connection wiring 24 is interrupted by the gap layer 60, the sealing layer 50 is not ruptured and thus the seal performance is maintained. Furthermore, since the fuse part 24a and the sealing layer 50 are formed in a noncontact fashion, the break would not be repaired by the pressure from the sealing layer 50, thereby causing no leak to occur again. Furthermore, since the bank 70 is provided so as to cover the side of the opening of the sealing layer 50 for defining the gap layer 60, it is possible to prevent entry of oxygen or moisture through the opening and provide the organic EL device with improved reliability.

### Third Embodiment

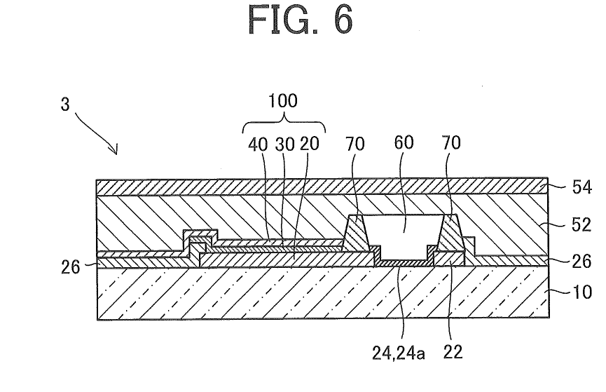

FIG. 6 is a cross-sectional view illustrating the structure of an organic EL device 3 according to a third embodiment of the present invention. The organic EL device 3 has a sealed structure which is sealed with a plate-shaped seal plate and different from the organic EL devices according to the aforementioned first and second embodiments which have a sealed structure sealed with a thin film.

The organic EL element 100, the power-supply wiring 22, and the connection wiring 24 having the fuse part 24a are provided on the substrate 10. For example, a seal plate 54 of a plate-shaped material such as a glass plate, plastic plate, or metal plate is provided above the substrate 10 with an adhesive layer 52 disposed therebetween. The adhesive layer 52 is provided so as to cover the entire region of the substrate 10 and embeds the organic EL element 100 therein. The bank 70 is provided to surround the fuse part 24a and blocks the entry of the adhesive layer 52 onto the fuse part 24a. This allows the gap layer 60 having the bank 70 as the sidewall to be formed above the fuse part 24a. That is, the adhesive layer 52 forms a partially hollow structure in which the gap layer 60 is embedded.

The organic EL device 3 is manufactured, for example, in the following processes. The first electrode 20, the power-supply wiring 22, and the connection wiring 24 having the fuse part 24a are formed on the substrate 10. Next, the bank 70 is formed so as to surround the fuse part 24a. The bank 70 is formed by depositing, for example, an organic material such as photosensitive polyimide and thereafter patterning the same by the exposure and development process. The bank 70 forms a partition wall for surrounding the connection wiring 24 that includes the fuse part 24a. For example, the bank 70 can be formed on the first electrode 20 and the power-supply wiring 22.

Then, the insulating film 26 is formed which has an opening above the first electrode 20 and the fuse part 24a. Next, the organic functional layer 30 is formed on the first electrode 20. Next, the second electrode 40 is formed which is connected to the organic functional layer 30 and extends in a direction orthogonal to the direction in which the power-supply wiring 22 extends.

Then, a sheet-shaped adhesive or the material of the adhesive layer 52 is affixed to the substrate 10 obtained through each of the aforementioned steps. As the sheet-shaped adhesive, for example, it is possible to employ an adhesive of a UV curable type. The UV curable type sheet adhesive has a solid sheet shape at room temperatures, and can be liquefied and flown by heating, and irradiated with ultraviolet radiation to be instantaneously and completely hardened. The sheet-shaped adhesive is provided above the surface of the substrate 10 so as to define a space inside the bank 70 (i.e., above the fuse part 24a). In other words, without entering into the bank 70, the sheet-shaped adhesive covers the gap above the fuse part 24a with the gap interposed therebetween. This allows a partially hollow structure to be formed inside the adhesive layer 52.

Subsequently, the seal plate 54 which is made of a plate-shaped material such as a glass plate, plastic plate, or metal plate is placed on the surface of the sheet-shaped adhesive. After that, the adhesive is liquefied by heat treatment, and then hardened with ultraviolet irradiation. Through each of the aforementioned steps, the organic EL device 3 is completed.

Note that the adhesive layer 52 is not limited to the aforementioned sheet-shaped adhesive, but a liquid adhesive may also be employed. For example, by spin coating, a thermosetting type or UV curable type silicone resin adhesive, which is a material of the adhesive layer 52, may be applied to and deposited on the substrate 10 obtained through each of the steps. Note that the component of the adhesive is not limited to a particular one. Furthermore, it is also acceptable to contain barium oxide powder in the adhesive to impart a hygroscopic function to the adhesive layer 52. The adhesive covers the space above the fuse part 24a without entering into the bank 70 by adjusting, e.g., the viscosity of the adhesive. That is, the adhesive becomes wet and expands while forming the gap layer 60 above the fuse part 24a. This allows a partially hollow structure. to be formed inside the adhesive layer 52. Note that liquid repellency processing such as fluorine-based plasma processing may be performed on the inner wall of the bank 70 or the surface of the connection wiring 24 that includes the fuse part 24a, thereby facilitating the formation of the gap layer 60. After that, the seal plate 54 is placed on the adhesive layer 52, and the liquid-state adhesive is hardened, e.g., by heat treatment or ultraviolet irradiation.

As in the case of the sealing with a thin film, in such an organic EL device having the sealed structure which is sealed with the plate-shaped seal plate, the connection wiring can properly have a break when an overcurrent flows therethrough. Furthermore, since the heat or impact caused by a break of the connection wiring 24 is interrupted by the gap layer 60, the seal plate 54 is not ruptured and thus the seal performance is maintained. Furthermore, since the fuse part 24a and the seal plate 54 are formed in a noncontact fashion, the break would not be repaired by the pressure from the seal plate 54, thereby causing no leak to occur again.

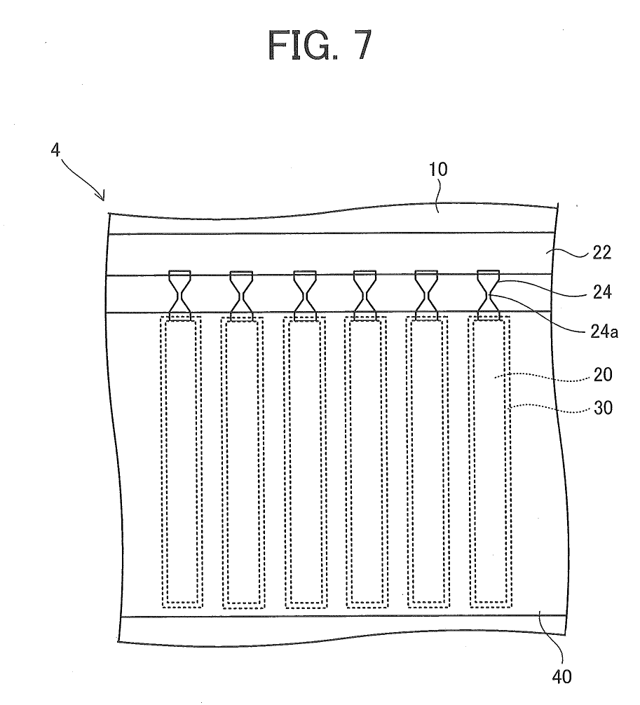

In each of the aforementioned embodiments, descriptions have been made, by way of example, to the display device that has a so-called dot matrix display mode in which the power-supply wirings 22 and the second electrodes 40 are arranged in a grid pattern and the organic EL elements 100 are disposed at each of these intersections. However, the present invention is not limited to such an arrangement. FIG. 7 is a plan view illustrating the structure of an organic EL device 4 in which the arrangement of the electrodes, the wirings, and the organic EL elements is modified.

In the organic EL device 4, a plurality of connection wirings 24 are connected to one of the power-supply wirings 22 formed on the substrate 10. While being collected at one position (or a plurality of positions), the plurality of connection wirings 24 are disposed side by side at equal intervals and each have the fuse part 24a as in each of the aforementioned embodiments. Each of the connection wirings 24 is connected to the first electrode 20 that is patterned in a strip shape. Provided on the first electrode 20 is the organic functional layer 30 that has the same strip shape. The second electrode 40 that is common to a plurality of organic EL elements 100 is provided on the organic functional layer 30. The second electrode 40 extends in parallel to the direction in which the power-supply wiring 22 extends. Note that the second electrode 40 may be separated for each organic EL element and have the same strip shape as that of the first electrode 20 or the organic functional layer 30. According to such a layout in which the connection wirings 24 are collected at one position, the fuse parts 24a can be collected at one position and thus facilitate patterning of the sealing layer (i.e., formation of the gap layer).

### REFERENCE SIGNS LIST

1, 2, 3, 4 Organic EL device
10 Substrate
20 First electrode
22 Power-supply wiring
24 Connection wiring
24a Fuse part
30 Organic functional layer
40 Second electrode
50 Sealing layer
52 Adhesive layer
54 Sealing plate
60 Gap-containing layer
70 Bank

1. An organic electroluminescent device comprising:
a substrate;
a first electrode layer provided on or above the substrate;
an organic functional layer that includes an organic material and is provided on or above the first electrode layer;
a second electrode layer provided on or above the organic functional layer;
a connection wiring provided on or above the substrate and connected to the first electrode layer or the second electrode layer; and
a sealing layer covering a layered structure including the first electrode layer, the second electrode layer, the organic functional layer, and the connection wiring, wherein
the connection wiring includes a fuse part to be broken due to an overcurrent, and the fuse part is in contact with a gap layer.

2. The organic electroluminescent device according to claim 1, wherein
the sealing layer includes an opening defining the gap layer, and
the fuse part has an upper face exposed in the opening from the sealing layer.

3. The organic electroluminescent device according to claim 2, comprising a bank covering a side of the opening of the sealing layer.

4. The organic electroluminescent device according to claim 1, wherein the sealing layer is formed with a thin film.

5. The organic electroluminescent device according to claim 1, wherein the sealing layer includes an adhesive layer formed to embed the gap layer on the substrate and a seal plate provided on or above the adhesive layer.

6. A method for manufacturing an organic electroluminescent device, comprising the steps of:
forming a first electrode layer on or above a substrate;
forming, on or above the first electrode layer, an organic functional layer containing an organic material;
forming a second electrode layer on or above the organic functional layer;
forming, on or above the substrate, a connection wiring connected to the first electrode layer or the second electrode layer and having a fuse part to be broken due to an overcurrent;
forming a sealing layer covering a layered structure including the first electrode layer, the second electrode layer, the organic functional layer, and the connection wiring; and
removing a portion covering an upper surface of the fuse part of the sealing layer.

7. The manufacturing method according to claim 6, comprising a step of forming a bank surrounding the fuse part before forming the sealing layer.

8. A method for manufacturing an organic electroluminescent device, comprising the steps of:
forming a first electrode layer on or above a substrate;
forming an organic functional layer containing an organic material on or above the first electrode layer;
forming a second electrode layer on or above the organic functional layer;
forming, on or above the substrate, a connection wiring connected to the first electrode layer or the second electrode layer and having a fuse part to be broken due to an overcurrent;
forming a bank surrounding the fuse part;
forming an adhesive layer covering a layered structure while forming a gap layer with the bank employed as a sidewall above the fuse part, the layered structure including the first electrode layer, the second electrode layer, the organic functional layer, and the connection wiring; and
forming a seal plate on or above the adhesive layer.

9. The organic electroluminescent device according to claim 2, wherein the sealing layer is formed with a thin film.

10. The organic electroluminescent device according to claim 3, wherein the sealing layer is formed with a thin film.

11. The organic electroluminescent device according to claim 2, wherein the sealing layer includes an adhesive layer formed to embed the gap layer on the substrate and a seal plate provided on or above the adhesive layer.

12. The organic electroluminescent device according to claim 3, wherein the sealing layer includes an adhesive layer formed to embed the gap layer on the substrate and a seal plate provided on or above the adhesive layer.
